(19) United States
(12) Patent Application Publication
(10) Pub. No.: US 2025/0233097 A1
(43) Pub. Date: Jul. 17, 2025

(54) SYSTEMS AND METHODS FOR REDUCING STRESS AND IMPROVING SURFACE ADHESION IN A DIE

(71) Applicant: SK Hynix NAND Product Solutions Corp. (dba Solidigm), Rancho Cordova, CA (US)

(72) Inventors: Zhijun Xu, Shanghai (CN); James Eldon Christie, Eagle Mountain, UT (US)

(21) Appl. No.: 18/567,729

(22) PCT Filed: Sep. 2, 2022
(86) PCT No.: PCT/CN2022/116715

§ 371 Date: Dec. 6, 2023

(51) Int. Cl. H01L 23/00; H01L 25/10

(52) U.S. Cl. CPC H01L 24/29; H01L 24/32; H01L 25/105; H01L 2224/29019; H01L 2224/32145

(57) ABSTRACT

A die, an integrated circuit (IC) device including two or more stacked dies, and a process of forming a die are provided. The die includes a circuit, a passivation layer arranged above the circuit and includes a top side and a bottom side, and a polyimide layer disposed on the top side of the passivation layer. The top side of the passivation layer includes portions of different respective heights extending vertically away from the circuit. A top side of the polyimide layer opposite the top side of the passivation layer includes portions of different respective heights extending vertically away from the circuit such that the surface area of the top side of the polyimide layer is increased compared to a planar top side.

### TECHNICAL FIELD

The present disclosure is related to a die for an integrated circuit (IC) device having two or more stacked dies, and more particularly, to an improved die for reducing stress and improving surface adhesion in an IC device having two or more stacked dies.

### SUMMARY

In accordance with the present disclosure, a die for a three-dimensional (3D) IC device for modulating wafer bow and die level warpage, and/or for improving die surface adhesion between stacked dies is provided. The die includes a circuit, a passivation layer including a top side and a bottom side and arranged above the circuit, and a polyimide layer disposed on the top side of the passivation layer. The top side of the passivation layer includes portions of different respective heights extending vertically away from the circuit.

In some embodiments, the top side of the passivation layer may include a plurality of projections extending away from a base of the top side.

In some embodiments, each of the plurality of projections may include respective sides, each of which is tapered such that the projection narrows as it extends away from the base.

In some embodiments, the sides of a projection of the plurality of projections may be each tapered at an angle.

In some embodiments, the projections may include projections of different heights extending away from the base of the top side.

In some embodiments, each of the plurality of projections may be one of a trapezoidal prism, a pyramid, or a triangular prism.

In some embodiments, an arrangement and shape of the plurality of projections may be based on the lattice orientation of silicon in the die and the size of the circuit.

In some embodiments, a top side of the polyimide layer opposite the top side of the passivation layer may include portions of different respective heights extending vertically away from the circuit such that the surface area of the top side of the polyimide layer is increased compared to a planar top side.

In some embodiments, an IC device is provided. The IC device includes a substrate and a first die arranged on the substrate, the first die including a first circuit; a first passivation layer including a top side and a bottom side and arranged above the first circuit; and a first polyimide layer disposed on the top side of the first passivation layer, a top side of the polyimide layer opposite the top side of the passivation layer including portions of different respective heights extending away from the first passivation layer. The IC further includes a die attach film (DAF) disposed on the top side of the first polyimide layer and a second die, the second die including a second circuit; a second passivation layer including a top side and a bottom side and arranged above the first circuit; and a second polyimide layer disposed on the top side of the first passivation layer. The second die is vertically stacked on top of the first die and attached to the first die by the DAF, which bonds the top side of the first polyimide layer to a bottom side of the second circuit opposite the second passivation layer.

In some embodiments, the IC device is a three-dimensional, floating-gate, NAND memory.

In some embodiments, a method for disposing a passivation layer is provided. The method includes disposing the passivation layer on a circuit layer, the passivation layer including a top side and a bottom side, and modulating the thickness of portions of the passivation layer such that the top side is non-planar.

In some embodiments, modulating the thickness of the portions may include etching away a thickness of the portions from the top side of the passivation layer.

In some embodiments, modulating the thickness of the portions may include applying a photolithography process to the top side of the passivation layer to modulate the thickness of the portions.

In some embodiments, the photolithography process may include using a reticle mask with portions that allows different respective percentages of leaky chrome to reach the top side of the passivation layer thereby modulating passivation thickness.

### BRIEF DESCRIPTION OF THE DRAWINGS

The following description includes discussion of figures having illustrations given by way of example of implementations of embodiments of the disclosure. The drawings should be understood by way of example, and not by way of limitation. As used herein, references to one or more “embodiments” are to be understood as describing a particular feature, structure, and/or characteristic included in at least one implementation. Thus, phrases such as “in one embodiment” or “in an alternate embodiment” appearing herein describe various embodiments and implementations, and do not necessarily all refer to the same embodiment. However, they are also not necessarily mutually exclusive.

FIG. 1 shows a simplified profile view of a 3D IC device;

FIG. 2 shows an illustrative profile view of an IC device, in accordance with some embodiments of the present disclosure;

FIGS. 3A-3C show an illustrative series of steps in a process for manufacturing the passivation layer of, for example, FIG. 2, in accordance with some embodiments of the present disclosure;

FIGS. 4A and 4B show an illustrative series of steps in a process for manufacturing the polyimide layer of, for example, FIG. 2, in accordance with some embodiments of the present disclosure;

FIG. 5 shows an illustrative profile view of a die, in accordance with some embodiments of the present disclosure;

FIG. 6 shows an illustrative profile view of another die, in accordance with some embodiments of the present disclosure;

FIGS. 7A-7D show illustrative top views of the geometry of the top side of a protective layer, in accordance with some embodiments of the present disclosure; and

FIG. 8 shows a flowchart of an illustrative process for fabricating a die, in accordance with some embodiments of the present disclosure.

### DETAILED DESCRIPTION

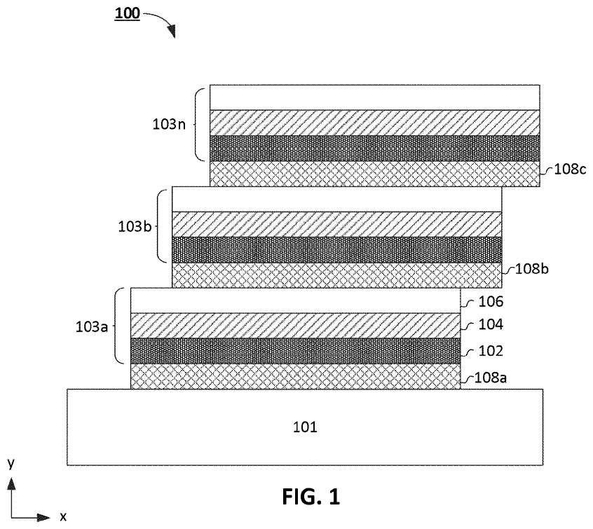

In order to increase chip density in IC devices (e.g., flash memory), multiple dies may be vertically stacked on a substrate (e.g., 3D IC device). FIG. 1 shows a simplified profile view of a 3D IC device 100. As shown, the IC device 100 includes a plurality of stacked dies 103a, 103b, 103n (collectively referred to as dies 103) vertically stacked (e.g., in the y-direction) on a substrate 101. Each of the dies 103 includes a circuit layer 102 containing one or more ICs, a passivation layer 104 arranged above the circuit layer 102, and a polyimide layer 106 arranged above the circuit layer. As shown, the die 103a is bonded to the substrate 101 by an adhesive layer 108a (e.g., a DAF), the die 103b is bonded to the polyimide layer 106 of the die 103a by another adhesive layer 108b, and the die 103n is bonded to the polyimide layer 106 of the IC die 103b by another adhesive layer 108c. In this approach, by vertically stacking a plurality of dies 103, chip density of the IC device 100 may be increased without substantially increasing the footprint of the IC device 100.

In some approaches, to further increase the chip density of IC device 100, wafer thickness (e.g., of the circuit layer 102) may be decreased and the number of vertically stacked dies 103 may be increased. However, as the wafer thickness decreases and the number of vertically stacked dies 103 increases (e.g., with each new silicon (Si) generation), the likelihood of wafer-level bow and die-level warpage increases. As a result, micro-cracks in the passivation layer, decreased adhesion between stacked dies (e.g., delamination), and cracks in the wafer may occur.

In accordance with the present disclosure, a die for a 3D IC device for modulating wafer bow and die level warpage, and/or for improving die surface adhesion between stacked dies is provided.

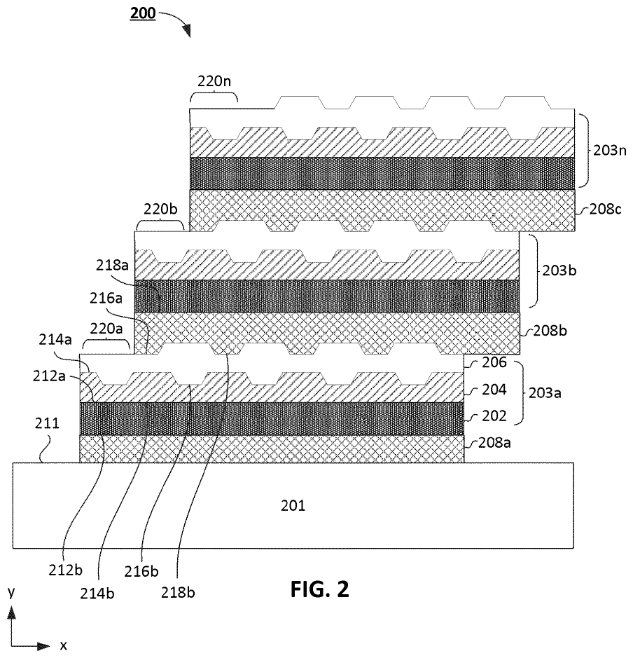

The subject matter of this disclosure may be better understood by reference to FIGS. 2-8.

FIG. 2 shows an illustrative profile view of an IC device 200, in accordance with some embodiments of the present disclosure. In some embodiments, the IC device 200 may be a solid-state storage memory including one or more packages of non-volatile memory dies. For example, the IC device 200 may be a 3D NAND-based flash memory (e.g., using floating gate technology). However, this is only one example, and the IC device 200 may be any IC memory device (e.g., volatile memory) or non-memory device that uses ICs.

As shown, the IC device 200 may include a plurality of dies 203a, 203b, 203n (collectively referred to as dies 203) vertically stacked on a substrate 201 (e.g., a mounting substrate). Although only three dies 203 are shown, it should be understood that any suitable number of the dies 203 may be vertically stacked on the substrate 201 (e.g., in the y-direction in the illustrated x-y plane). In one example, 16 dies 203 are vertically stacked on the substrate 201. However, this is only one example. The plurality of stacked dies 203 may include more or less than 16 stacked dies 203 (e.g., 2, 4, 8, 32, 64, 128, etc.) and the number need not be an even number. In some embodiments, as shown, the plurality of dies 203 may be stacked with a lateral offset (e.g., in the x-direction in the illustrated x-y plane) to expose a wire bond pad area (220a, 220b, 220n) on each of the dies 203 for interconnecting the dies 203 through wire boded connections (e.g., a shingle-stack or stair-step configuration). However, it should be understood that the dies 203 may be arranged in other vertical stack configurations, in which case other suitable wire bonding configurations may be used. For example, the dies 203 may also be edge-aligned (e.g., in which case film-over-wire bonding may be used).

As shown, each of the dies 203 may include a circuit layer 202 containing one or more ICs (collectively referred to as a circuit), a passivation layer 204 arranged above the circuit layer 202, and a polyimide layer 206 arranged above the passivation layer 204. It should be understood that the dies 203 may include other suitable layers, contact pads, and elements (not shown). For example, a metal layer (e.g., an aluminum layer) may be disposed between circuit layer 202 and passivation layer 204. However, as these components are known to those skilled in the art, these components, as well as other well-known components, are not shown, for simplicity of illustration and discussion and so not as to obscure the disclosure.

The substrate 201 may be a mounting substrate or carrier substrate. As shown, the substrate 201 includes a top side 211 on which the plurality of dies 203 may be stacked. The substrate 201 may include silicon, glass, epoxy resin, any other suitable material, or any combination thereof. In some embodiments, the substrate 201 may include one or more conductive pads configured to connect to the circuit layer 202 (e.g., via solder bumps).

The circuit layer 202 may comprise one or more ICs formed on a silicon (Si) wafer. In some embodiments, the thickness of the Si wafer may be less than or equal to fifty-five microns (μm). However, this is only one example, and the thickness of the Si wafer may be any suitable thickness (e.g., greater than fifty-five μm). In some embodiments, the Si wafer may comprise a 100-degree or 110-degree lattice Si (e.g., the arrangement of the lattice structure within the silicon). As shown, the circuit layer 202 includes a top side 212a and a bottom side 212b. Although a Si wafer is described, it should be understood that the one or more ICs may be formed on other suitable wafer materials (e.g., gallium arsenide (GaAs), gallium nitride (GaN), and silicon carbide (SiC)). Additionally, the circuits formed on the wafer may include components that match the material of the wafer or that are formed of different materials (e.g., GaAs components on a Si wafer).

The passivation layer 204 is arranged above the circuit layer 202 (e.g., in the y-direction) and may protect the circuit layer 202 from damage (e.g., electrical and/or mechanical) and contamination (e.g., a first protection layer). In some embodiments, as described in greater detail below, the passivation layer 204 may be a hard coat protection layer fabricated using a modified wafer (hard coat) passivation process. Although the passivation layer 204 is shown as a single layer, it should be understood that the passivation layer 204 may include a plurality of layers (e.g., according to the modified passivation process). In some embodiments, the passivation layer 204 comprises at least one silicon dioxide (Sio2) layer and/or a combination of oxynitride (ONON) layers.

As shown, the passivation layer 204 includes a top side 214a and a bottom side 214b. In some embodiments, the bottom side 214b may be a planar surface arranged above and facing the top side 212a of the circuit layer 202, while the top side 214a may be a non-planar surface including portions of different respective heights (e.g., a plurality of projections) extending vertically away from the circuit layer 202 (in the y-direction). As explained in further detail below, the geometry of the top side 214a of the passivation layer 204 may be configured to modulate wafer bow (of the circuit layer 202) and warpage of the die 203 (e.g., die-level warpage) in the IC device 200.

The polyimide layer 206 is disposed on the top side 214a of the passivation layer 204. The polyimide layer 206 may be an insulating layer that further protects the die 203 (e.g., a second protective layer). In some embodiments, as described in greater detail below, the polyimide layer 206 may be fabricated using a modified polyimide (soft coat) protective coating process. For example, the polyimide layer 206 may be fabricated using a modified polyimide reticle layout design to enable defined photo exposure patterns to increase the surface area and reduce wafer Bow/Die warpage, as explained in greater detail below. As shown, the polyimide layer 206 includes a top side 216a and a bottom side 216b. The bottom side 216b of the polyimide layer 206 may conform to the geometry of the top side 214a of the passivation layer 204 (e.g., as a result of being disposed on the top side 214a of the passivation layer 204), while the top side 216a of the polyimide layer 206 may be a non-planar surface including portions of different respective heights (e.g., a plurality of projections) extending vertically away from the passivation layer 204 (in the y-direction). As explained in further detail below, the added geometry of the top side 216a of the polyimide layer 206 may improve die surface adhesion between stacked dies by increasing the surface area of the top side 216a of the polyimide layer 206 for an adhesive layer 208b to bond to (e.g., compared to the planar top side shown in FIG. 1).

As shown, the first die 203a may be bonded to the substrate 201 by an adhesive layer 208a, which adheres the bottom side 212b of the circuit layer 202 of the first die 203a to the top side 211 of the substrate 201. The second die 203b may be bonded to the top side 216a of the polyimide layer 206 of the first die 203a by the adhesive layer 208b, which adheres the top side 216a of the polyimide layer 206 (by a bottom surface 218b of the adhesive layer 208b) of the first die 203a to a bottom side 212b of the circuit layer 202 of the second die 203b (by a top surface 218a of the adhesive layer 208b). Similarly, the third die 203n may be bonded to the top side 216a of the polyimide layer 206 of the second die 203a by an adhesive layer 208c, which adheres the top side 216a of the polyimide layer 206 of the second die 203a to a bottom side 212b of the circuit layer 202 of the third die 203n. In some embodiments, each of the adhesive layers 208a, 208b, 208c (collectively referred to as adhesive layers 208) may comprise a die attach film (DAF). In some embodiments, the DAF may include a thermosetting or thermoplastic resin.

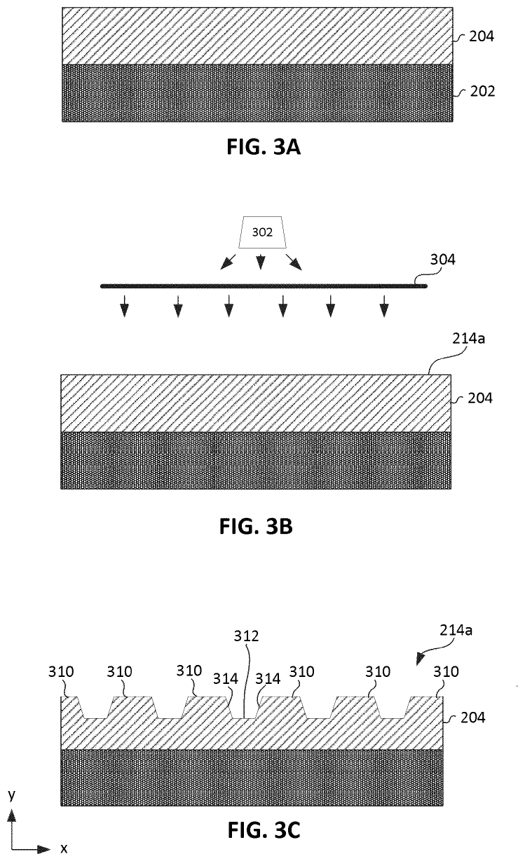

FIGS. 3A-3C show an illustrative series of steps in a process for manufacturing the passivation layer 204 of, for example, FIG. 2, in accordance with some embodiments of the present disclosure. In some embodiments, the process is a modified wafer passivation process.

FIG. 3A shows the passivation layer 204 arranged on the circuit layer 202. In some embodiments, as shown, the passivation layer 204 (as disposed) may have a substantially planar top surface. Additionally, although the passivation layer 204 is illustrated as a single layer, it should be understood that the passivation layer 204 may be comprised of a plurality of layers disposed on top of one another, as described above. For example, the passivation layer 204 may comprise at least one Sio2 layer and/or a combination of ONON layers. However, these are only examples, and the passivation layer 204 may comprise any suitable layers.

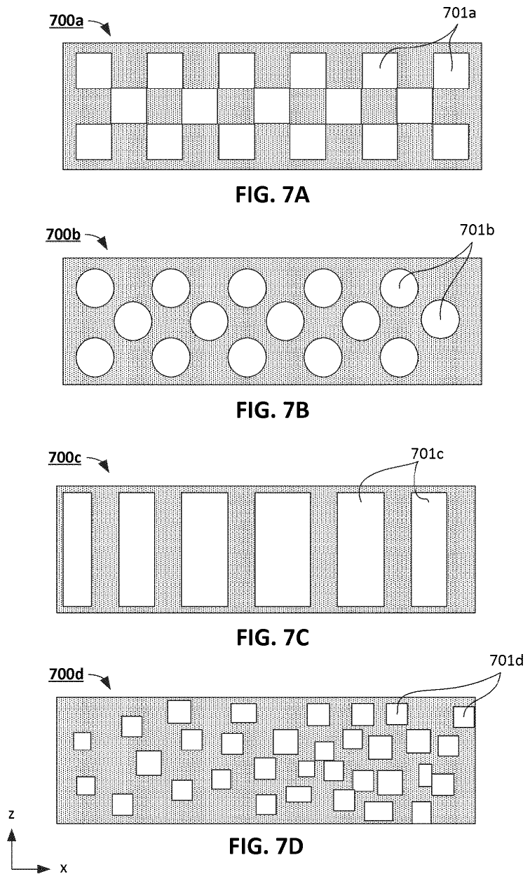

FIG. 3B shows a photolithography process applied to the top side 214a of the passivation layer 204 of FIG. 3A. The photolithography process may comprise selectively leaking light (from light 302) around the chrome of a reticle 304 to allow different percentages of light (“leaky chrome”) to reach the top side 214a of the passivation layer 204, thereby modulating thickness of the passivation layer 204 (e.g., during a subsequent etching step). The reticle 304 may be configured with a pattern corresponding to the desired geometry of the top side 214a of the passivation layer 204, as explained in greater detail with reference to FIGS. 7A-7D.

FIG. 3C shows the resulting geometry of the top side 214a of the passivation layer 204, following an etch process after the photolithography process of FIG. 3B. As shown, the top side 214a of the passivation layer 204 comprises a plurality of projections 310 extending away from a base 312 (e.g., a lower elevation). As shown, the respective sides 314 of each of the projections 310 are tapered such that the projection narrows as it extends away from the base 312. In some embodiments, the angle of taper of the sides 314 may be varied between 30 and 45 degrees, based on the desired geometry for modulating wafer bow and die-level warpage. In some embodiments, the angle of taper of the sides 314 may be varied by other suitable degrees.

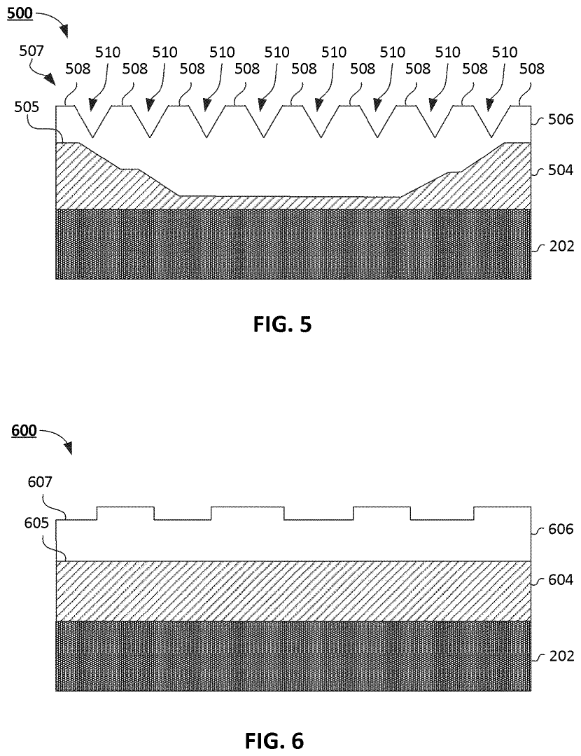

In some embodiments, the wafer bow and die-level warpage may be determined experimentally (e.g., by measuring the wafer bow and die-level warpage of dies of an IC device) (e.g., the IC device illustrated in FIG. 1). In some embodiments, the wafer bow and die-level warpage may be determined based on the design and configuration of the IC device. Based on the determined wafer bow and die-level warpage, the shape and thickness of the passivation layer 204 may be modulated to compensate for the determined wafer bow and die-level warpage. For example, the shape and thickness of the passivation layer 204 may be modulated to introduce geometries (shapes, patterns, features, spacing of features, etc.) that provide desired strength and stability for the desired application and compensate for the determined wafer bow and die-level warpage. It is understood that, in the field of mechanical engineering, various geometries provide desired results. Thus, the shape and thickness of the passivation layer 204 may be modulated according to mechanical engineering principles to compensate for the determined wafer bow and die-level warpage. For example, FIG. 5 shows a passivation layer 204 having a geometry that provides desired strength and stability for another IC device.

Although each of the plurality of projections 310 is shown as a trapezoidal prism, it should be understood that the projections 310 may be formed in other geometries such as a pyramid, a triangular prism, a sphere, or any other suitable geometries based on known principles of mechanical engineering. Additionally, although the plurality of projections 310 are shown as being regularly spaced (e.g., along the x-direction), it should be understood that the projections 310 may be irregularly spaced to provide the desired strength and stability for the desired application. In some embodiments, the arrangement and shape of the projections 310 are based on the lattice orientation of Si in the circuit layer 202 (e.g., with respect to the arrangement of the IC) and the size of the circuit layer 202. For example, the arrangement of the IC of a die with respect to the lattice orientation of Si of the wafer may contribute to wafer bow and die-level warpage of the stacked dies. Thus, the arrangement and shape of the projections 310 may compensate for this wafer bow and die-level warpage.

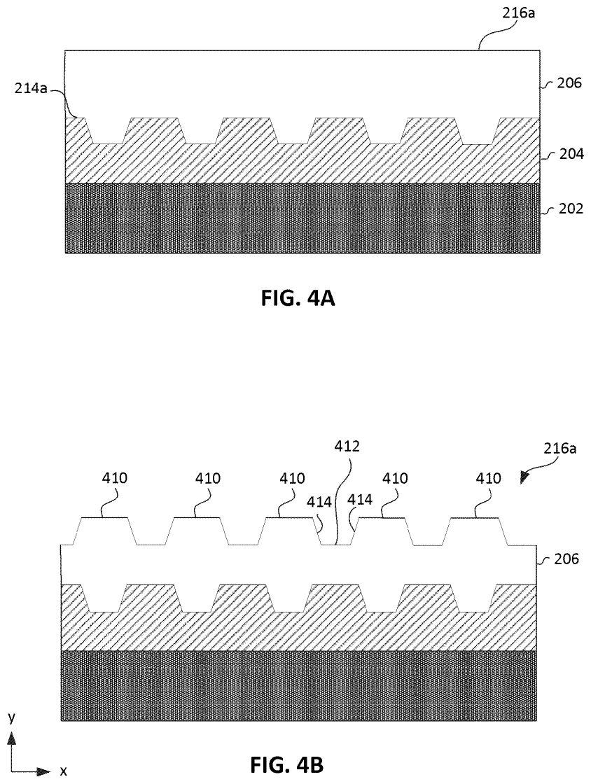

FIGS. 4A and 4B show an illustrative series of steps in a process for manufacturing the polyimide layer 206 of, for example, FIG. 2, in accordance with some embodiments of the present disclosure. In some embodiments, the process is a modified polyimide protective coating process.

FIG. 4A shows the polyimide layer 206 disposed on the top side 214a of the passivation layer 204 (e.g., of FIG. 3B). In some embodiments, as shown, the top side 216a of the polyimide layer 206 (as disposed) may be substantially planar. However, this is only an example, and the top side 216a of the polyimide layer 206 may retain some of the geometry from the top side 214a of the passivation layer 204 as a result of being disposed on the top side 214a of the passivation layer 204.

FIG. 4B shows the resulting geometry of the top side 216a of the polyimide layer 206, following a modulation process. In some embodiments, the modulation process may be the photolithography (and etch) process described above with reference to FIG. 3B. In some embodiments, the modulation process may be a pad etch process. As shown, the top side 216a of the polyimide layer 206 comprises a plurality of projections 410 extending away from a base 412 (e.g., a lower elevation). As shown, the respective sides 414 of each of the projections 410 are tapered such that the projection narrows as it extends away from the base 412. In some embodiments, the angle of taper of the sides 414 may be varied between 30 and 45 degrees. However, this is only one example, and the respective sides 414 of each of the projections 410 may not be tapered, as shown in FIG. 5. In some embodiments, the angle of taper of the sides 414 may be varied by other suitable degrees. In some embodiments, the thickness of the polyimide layer 206 may be modulated between 1.7 μm and 3.5 μm. However, this is only an example, and the thickness of the polyimide layer 206 may be any suitable thickness.

In some embodiments, because the top side 216a of the polyimide layer 206 is a non-planar surface, the surface area of the top side 216a of the polyimide layer 206 is increased (e.g., compared to a planar surface). Thus, adhesion to the adhesion layer 208 may be improved, resulting to an improved die surface adhesion between the stacked dies 203 of FIG. 2.

FIG. 5 shows an illustrative profile view of a die 500, in accordance with some embodiments of the present disclosure. The die 500 may correspond to the die 203 of FIG. 2, except that the geometry of a top surface 505 of a passivation layer 504 and a top surface 507 of a polyimide layer 506 may be configured differently to provide the desired strength and stability for another application. For example, as shown, the top surface 505 of the passivation layer 504 may be stepped down towards the center of the die 500, while the top surface 507 of the polyimide layer 506 may comprise a plurality of projections 508 extending away from the passivation layer 504 and formed by removing pyramid-shaped portions 510 of the top surface.

FIG. 6 shows an illustrative profile view of a die 600, in accordance with some embodiments of the present disclosure. In some embodiments, where modulation of the passivation layer 604 is not required to modulate wafer bow (of the circuit layer 202) and warpage of the die 203 (e.g., die-level warpage) (e.g., for circuit layers 202 having a large wafer thickness), it may still be desirable to improve the adhesion between stacked dies. For example, as shown, the passivation layer 604 may comprise a planer top side 605, while the top side 607 of the polyimide layer 606 may include a plurality of rectangular projections (e.g., formed by a pad etch process) to increase the surface area of the top side 607 of the polyimide layer 606. However, this is only one example, and the top side 607 of the polyimide layer 606 may be modulated in any suitable manner.

FIGS. 7A-7D show illustrative top views of the geometry of the top side of a protective layer, in accordance with some embodiments of the present disclosure. The top side (700a, 700b, 700c, 700d) may correspond to any of the top sides of the passivation layers (204 or 504) or polyimide layers (206, 506, or 606) described above. In some embodiments, the patterns illustrated in FIGS. 7A-7D may correspond to the pattern of a reticle (e.g., the reticle 304 of FIG. 3) used in a photolithography process step in creating the geometry of the respective top sides, as described above. It should be understood that the illustrated patterns may represent the shape of the base of features, but that side profiles of the features may be modulated at an angle as discussed above (e.g., by a 45-degree modulation process, or any other suitable degrees). Although four patterns are shown, these are only examples, and the geometry of the top side of a protective layer may have any suitable pattern based on the desired strength and stability for the desired application.

FIG. 7A shows an illustrative top view of a top side 700a of a protective layer. The top side 700a may include a plurality of square portions 701a where the thickness of the protective layer is decreased. As shown, the plurality of square portions 701a may be arranged in a checkerboard pattern.

FIG. 7B shows an illustrative top view of a top side 700b of a protective layer. The top side 700b may include a plurality of circular portions 701b where the thickness of the protective layer is decreased. As shown, the plurality of circular portions 701b may be arranged in a checkerboard pattern.

FIG. 7C shows an illustrative top view of a top side 700c of a protective layer. The top side 700c may include a plurality of rectangular portions 701c where the thickness of the protective layer is decreased. As shown, the plurality of rectangular portions 701c may be regularly spaced from each other, but may have different sizes.

FIG. 7D shows an illustrative top view of a top side 700d of a protective layer. The top side 700d may include a plurality of rectangular portions 701d where the thickness of the protective layer is decreased. As shown, the density of rectangular portions 701d may increase along the x-direction. Additionally, the size of the rectangular portions 701d may vary based on the desired strength and stability for the desired application.

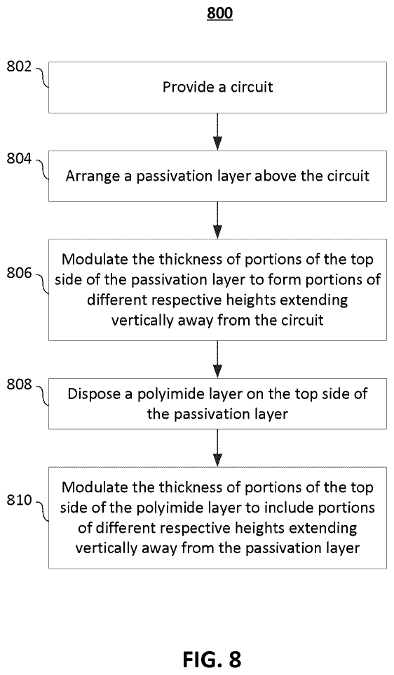

FIG. 8 shows a flowchart of an illustrative process 800 for fabricating a die, in accordance with some embodiments of the present disclosure.

At step 802, a circuit is provided. The circuit may be the circuit layer 202, as described above in FIG. 2.

At step 804, a passivation layer (e.g., a first protective layer) is arranged above the circuit. The passivation layer may be the passivation layer 204 (or 504), as described above in FIGS. 2 and 5.

At step 806, the thickness of portions of the top side of the passivation layer is modulated to form portions of different respective heights extending vertically away from the circuit. For example, a photolithography (and etch) process may be applied to the top side 214a of the passivation layer 204, as described above in FIGS. 3B and 3C. The passivation layer may also be the passivation layer 504, as described in FIG. 5. The resulting geometry of the top side of the passivation layer may compensate for the determined wafer bow and die-level warpage of the die 203, as described above.

At step 808, a polyimide layer may be disposed on the top side of the passivation layer. The polyimide layer may be the polyimide layer 206, as described above in FIG. 4A.

At step 810, the thickness of portions of the top side of the polyimide layer may be modulated to form portions of different respective heights extending vertically away from the passivation layer. For example, a photolithography and/or etch process may be applied to the top side 216a of the polyimide layer 206, as described above in FIG. 4B. The polyimide layer may also be the polyimide layer 506 or 606, as described above in FIGS. 5 and 6. The resulting geometry of the top side of the polyimide layer may increase the surface area of the top side (e.g., compared to a planar surface), thereby improving die surface adhesion between stacked dies, as described above.

The foregoing is merely illustrative of the principles of this disclosure and various modifications may be made by those skilled in the art without departing from the scope of this disclosure. The above-described embodiments are presented for purposes of illustration and not of limitation. The present disclosure also can take many forms other than those explicitly described herein. Accordingly, it is emphasized that this disclosure is not limited to the explicitly disclosed methods, systems, and apparatuses, but is intended to include variations to and modifications thereof, which are within the spirit of the following claims.

What is claimed is:

1. A die comprising:
a circuit;
a passivation layer comprising a top side and a bottom side, the passivation layer arranged above the circuit, wherein the top side of the passivation layer comprises portions of different respective heights extending vertically away from the circuit; and
a polyimide layer disposed on the top side of the passivation layer.

2. The die of claim 1, wherein the top side of the passivation layer comprises a plurality of projections extending away from a base of the top side.

3. The die of claim 2, wherein each of the plurality of projections comprise respective sides and wherein the respective sides of each of the plurality of projections are tapered such that the projection narrows as it extends away from the base.

4. The die of claim 3, wherein the sides of a projection of the plurality of projections are each tapered at an angle.

5. The die of claim 2, wherein the projections comprise projections of different heights extending away from the base of the top side.

6. The die of claim 2, wherein each of the plurality of projections is one of a trapezoidal prism, a pyramid, or a triangular prism.

7. The die of claim 2, wherein an arrangement and shape of the plurality of projections are based on the lattice orientation of silicon in the die and the size of the circuit.

8. The die of claim 1, wherein a top side of the polyimide layer opposite the top side of the passivation layer comprises portions of different respective heights extending vertically away from the circuit such that the surface area of the top side of the polyimide layer is increased compared to a planar top side.

9. An integrated circuit (IC) device comprising:
a substrate;
a first die arranged on the substrate, the first die comprising:
a first circuit;
a first passivation layer comprising a top side and a bottom side, the first passivation layer arranged above the first circuit; and
a first polyimide layer disposed on the top side of the first passivation layer, wherein a top side of the polyimide layer opposite the top side of the passivation layer comprises portions of different respective heights extending away from the first passivation layer;
a die attach film (DAF) disposed on the top side of the first polyimide layer; and
a second die comprising:
a second circuit;
a second passivation layer comprising a top side and a bottom side, the second passivation layer arranged above the first circuit; and
a second polyimide layer disposed on the top side of the first passivation layer,
wherein the second die is vertically stacked on top the first die and attached to the first die by the DAF, the DAF bonding the top side of the first polyimide layer to a bottom side of the second circuit opposite the second passivation layer.

10. The IC device of claim 9, wherein the top side of the first polyimide layer comprises a plurality of projections extending away from a base of the top side.

11. The IC device of claim 10, wherein each of the plurality of projections comprise respective sides and wherein the respective sides of each of the plurality of projections are tapered such that the projection narrows as it extends away from the base.

12. The IC device of claim 11, wherein the sides of a projection of the plurality of projections are each tapered at an angle.

13. The IC device of claim 10, wherein each of the plurality of projections is one of a trapezoidal prism, a pyramid, or a triangular prism.

14. The IC device of claim 9, wherein the portions of different respective heights of the first polyimide layer increase the surface area of the top side of the first polyimide layer compared to a planar top side.

15. The IC device of claim 9, wherein:
the top side of the first passivation layer comprises portions of different respective heights extending vertically away from the first circuit; and
the top side of the second passivation layer comprises portions of different respective heights extending vertically away from the second circuit.

16. The IC device of claim 9, wherein the IC device is a three-dimensional, floating-gate, NAND memory.

17. A method for disposing a passivation layer, the method comprising:
disposing the passivation layer on a circuit layer, the passivation layer comprising a top side and a bottom side; and
modulating thickness of portions of the passivation layer such that the top side is non-planar.

18. The method of claim 17, wherein modulating the thickness of the portions comprises etching away a thickness of the portions from the top side of the passivation layer.

19. The method of claim 17, wherein modulating the thickness of the portions comprises applying a photolithography process to the top side of the passivation layer to modulate the thickness of the portions.

20. The method of claim 19, wherein the photolithography process comprises using a reticle mask with portions that allows different respective percentages of leaky chrome to reach the top side of the passivation layer thereby modulating passivation thickness.
